(19) United States
(12) Patent Application Publication
(10) Pub. No.: US 2007/0177424 A1
(43) Pub. Date: Aug. 2, 2007

(54) Device with n-time pad and a method of managing such a pad

(76) Inventor: Martin Sadler, Bristol (GB)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/489,749

(22) Filed: Jul. 17, 2006

(30) Foreign Application Priority Data
Sep. 29, 2005 (GB) 0519842.9
Oct. 28, 2005 (GB) 0521935.7

(51) Int. Cl. G11C 16/04

(52) U.S. Cl. 365/185.04

(57) ABSTRACT

Data from an n-time pad is used in security-related tasks. To accommodate use of the pad with security-related tasks of different security ratings, the maximum number of times any particular data from the pad is used is determined by the security rating of the highest-security application using that data.

### FIELD OF THE INVENTION

The present invention relates to a device with an n-time pad for use in security-related tasks, and to a method of managing an n-time pad.

### BACKGROUND OF THE INVENTION

As is well known, two parties that posses the same secret random data can provably achieve both unbreakable secure communication using the Vernam cipher, and discrimination between legitimate messages and false or altered ones (using, for example, Wegman-Carter authentication). In both cases, however, data used from the secret random data shared by the parties must not be re-used. The term “one-time pad” is therefore frequently used to refer to the secret random data shared by the parties and this term, or its acronym “OTP”, is used herein for secret random data shared by more than one party. Although for absolute security the one-time pad data must be truly random, references to one-time pads (OTP) herein includes secret data that may not be truly random but is sufficiently random as to provide an acceptable degree of security for the purposes concerned.

The fact that the OTP data is effectively consumed when used gives rise to a major drawback of the employment of OTP cryptographic systems, namely that the OTP must be replenished.

One approach to sharing new OTP data between two parties is for one party to generate the new OTP data and then have a copy of the data physical transported in a storage medium to the other party. This is costly to do, particularly where it needs to be done frequently; furthermore, it may not be feasible to adopt this approach (for example, where one of the parties is a communications satellite).

Another approach is to send the OTP data over a communications link encrypted using a mathematically-based encryption scheme. However, this approach effectively reduces the security level to that of the encryption scheme used; since no such schemes are provable secure and may well prove susceptible to attack as a result of advances in quantum computing, this approach is no better than replacing the intended OTP system with a mathematically-based scheme.

More recently, quantum key distribution (QKD) methods and systems have been developed which enable two parties to share random data in a way that has a very high probability of detecting any eavesdroppers. This means that if no eavesdroppers are detected, the parties can have a high degree of confidence that the shared random data is secret. QKD methods and systems are described, for example, in U.S. Pat. No. 5,515,438 and U.S. Pat. No. 5,999,285. In known QKD systems, randomly polarized photons are sent from a transmitting apparatus to a receiving apparatus either through a fiber-optic cable or free space.

As a consequence of the actual and perceived problems of sharing secret random data, OTP cryptographic systems have generally only been used in applications where the security requirements are paramount such as certain military and government applications.

Because OTP cryptography is generally only employed where very high security is needed, the types of system where it is used are those where other components of the overall system do not significantly compromise the level of security provided by OTP cryptography. In particular, there is little point in using OTP cryptography for passing secret messages between parties if the messages are to be stored or subsequently transmitted in a manner that is significantly less secure. Furthermore, the storage of the OTP data itself represents a security threat and unless the OTP data can be stored in a highly secure manner, it is better to share OTP data only at a time immediately before it is to be consumed.

It is known to use re-ure data from a one-time pad in which case the pad is referred to as an “n-time” pad where n is an integer indicating the number of re-uses permitted. However, n-time pads are not favored because of the reduced security implicit in repeated use of the pad data.

### SUMMARY OF THE INVENTION

According to one aspect of the present invention, there is provided a method of managing an n-time pad from which data is used in security-related tasks, wherein in order to accommodate use of the pad with security-related tasks of different security ratings, the maximum number of times any particular data from the pad is used is determined by the security rating of the highest-security application using that data.

According to another aspect of the present invention, there is provided a device comprising:
a memory for holding an n-time pad and usage-related values concerning usage of data from the n-time pad, and
a consumption arrangement for using data from the n-time pad in executing security-related tasks
   wherein, in order to accommodate use of the pad with security-related tasks of different security ratings, the consumption arrangement is so arranged that the maximum number of times any particular data from the pad is used is determined by the security rating of the highest-security application using that data.

### BRIEF DESCRIPTION OF THE DRAWINGS

Embodiments of the invention will now be described, by way of non-limiting example, with reference to the accompanying diagrammatic drawings, in which:

FIG. 1 is a diagram of a generalised form of user OTP device adaptable for use in embodiments of the invention;

FIG. 2A is a diagram illustrating the use of a trusted data store to transfer OTP data;

FIG. 2B is a diagram illustrating the use of a first form of trusted random data generator to generate and distribute OTP data;

FIG. 2C is a diagram illustrating the use of a second form of trusted random data generator to generate and distribute OTP data;

FIG. 3 is a diagram depicting a user OTP device interacting with a distributed data processing system;

FIG. 4 is a diagram illustrating an example variable-n-time pad of an embodiment of the present invention; and

FIG. 5 is a flow chart illustrating a method of managing the variable-n-time pad of FIG. 4.

### BEST MODE OF CARRYING OUT THE INVENTION

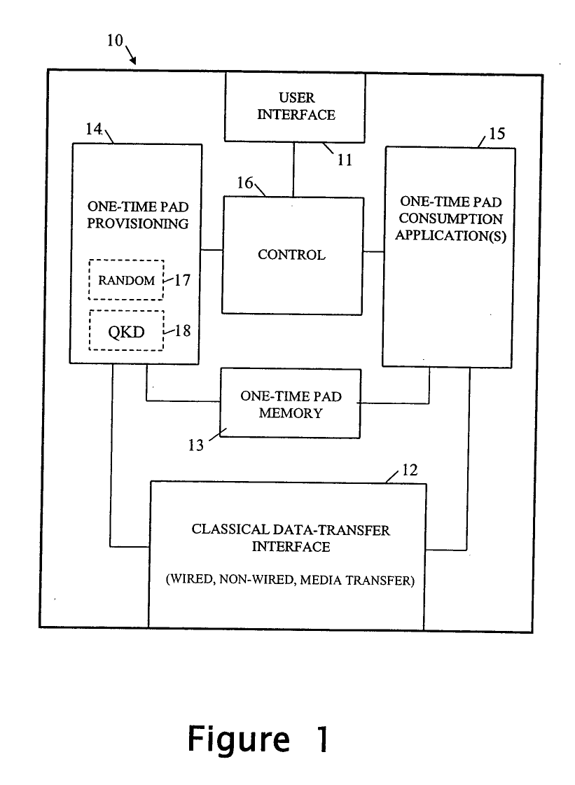

FIG. 1 shows, in generalized form, a user OTP device 10 for storing and using one-time pad data for various applications such as, for example, encryption and identification. Preferred embodiments of the device 10 are portable in form and are, for example, constituted by hand-held devices such as mobile phones and PDAs; however, other embodiments of the apparatus 10 can be of non-portable form such as a personal desktop computer.

In use, the OTP device 10 is intended to communicate with OTP apparatus having access to the same secret random data as the device 10 in order to conduct an OTP interaction (that is, an interaction requiring use of the same OTP data by the device and apparatus). Such OTP apparatus is hereinafter referred to as the “complementary OTP apparatus” with respect to the device 10; this apparatus can be of the same general form as the user OTP device 10 or can be of a different form and/or form part of a distributed system as will be described more fully hereinafter. Generally, the complementary OTP apparatus will be shown with a circular boundary in the Figures and will be referenced ‘20’.

The User OTP Device 10

The user OTP device 10 comprises the following functional blocks:
a user interface block 11 for interfacing with a user;
a classical data-transfer interface 12 for transferring data to and/or from external entities by wired or non-wired means, or by media transfer;
a memory 13 for storing OTP data;
an OTP provisioning block 14 which, through interaction with an external entity, is arranged to provide new secret random data for initializing or replenishing the memory 13 with OTP data;
an OTP consumption block 15 for carrying out one or more security-related applications that consume OTP data stored in memory 13; and
a control block 16 for controlling and coordinating the operation of the other blocks in response to inputs received through the user interface 11 and the data-transfer interface 12.

Typically, the functional blocks 11 to 16 are implemented using a program-controlled processor together with appropriate specialized sub-systems. Further details of each block are given below for the case where a processor-based system (including a main processor and associated memory) is used to carry out at least most of the data processing tasks of the device 10, such tasks including, in particular, the control and coordination tasks of control block 16 and the running of the security applications embodying the OTP consumption block 15.

User Interface 11

The user interface 11 typically comprises an LCD display and an input keypad but may also include audio input and/or output means.

Classical Data-Transfer Interface 12

The classical data-transfer interface 12 can comprise a non-wired interface such as a Bluetooth (Trademark) wireless interface or an IrDA infrared interface; however, a wired interface can alternatively or additionally be provided such as an USB interface (as used herein, the term “wired” is to be understood broadly to cover any type of interface that requires electrical elements to be brought into physical contact). For circumstances where transit delay is not an issue, it is also possible to implement the data-transfer interface 12 as a removable storage medium and related read/write arrangement.

OTP Memory 13

The OTP memory 13 can be part of the general memory associated with the main processor of device 10 or can be formed by a separate memory. In either case, the OTP data is preferably secured against unauthorized access by one or more appropriate technologies. For example, the memory 13 can all be provided in a tamper-resistant hardware package. Alternatively, a protected storage mechanism can be used in which all but the root of a hierarchy (tree) of encrypted data objects is stored in ordinary memory, the root of the hierarchy being a storage root key which is stored in a tamper-resistant hardware package and is needed to decrypt any of the other data objects of the hierarchy. Furthermore, trusted platform techniques can be used to ensure that only authorized software can access the OTP data. It is also possible to use QRAM (Quantum RAM) technologies.

Where the device 10 is designed such that OTP data is consumed immediately following its provisioning, the security requirements of memory 13 can be reduced (unless the device 10 is designed to operate unattended).

OTP Provisioning Block 14

With regard to the OTP provisioning block 14, the most secure way to share secret random data is to use a quantum key distribution method such as described in the documents referenced in the introduction to the present specification. In this case, the OTP provisioning block is provided with a QKD subsystem 17 that can be either a QKD transmitter or a QKD receiver. It is relatively straightforward to incorporate a QKD transmitter within a hand-held device and then to provide a cradle or similar mechanical arrangement to ensure that the device is properly optically aligned to interact with a fixed QKD receiver subsystem. In fact, it is possible to dispense with a mechanical alignment arrangement by the use of an automated or semi-automated alignment system such as is disclosed in our co-pending U.S. patent application Ser. No. 11/454,624, filed 16 Jun. 2006.

The OTP provisioning block 14 need not be built around a QKD subsystem and a number of alternative embodiments are possible. Thus, in one such alternative embodiment the OTP provisioning block 14 is simply be arranged to store to the OTP memory 13, secret random data received via the data-transfer interface 12 from either:
(i) OTP apparatus seeking to share secret random data with the device 10 either directly or via a trusted data store;
(ii) a trusted random data generator that has the role of generating secret random data and passing it both to the user device 10 and to OTP apparatus with which the device 10 is wishing to interact using shared OTP data

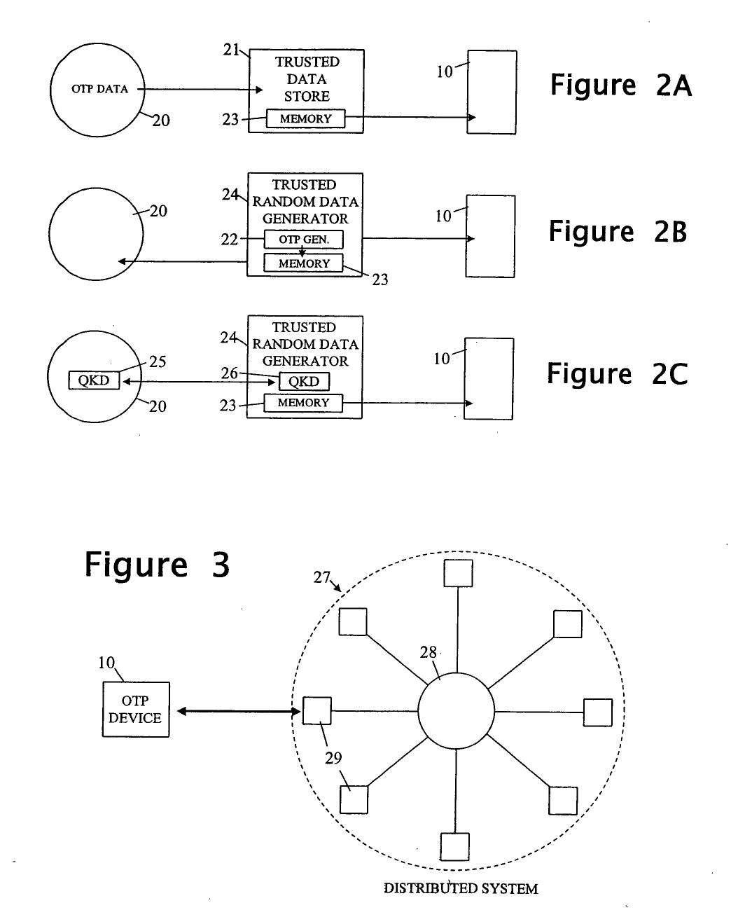

FIG. 2A illustrates the use of a trusted data store 21 for transferring secret random data to the device 10. In FIG. 2A, secret random data provided by the complementary OTP apparatus 20 is first passed to the trusted data store where it is held in memory 23 before being subsequently transferred to the OTP device 10. The trusted data store 21 can be infrastructure equipment or stand-alone equipment such as a hand-held device.

FIG. 2B illustrates the use of a trusted random data generator 24. The trusted generator 24 includes a random data generation arrangement 22 for generating the random data, this data being generated at a time that the trusted random data generator 24 is in communication with the device 10 so that the random data can be passed immediately to the device 10. The trusted random data generator 24 also stores the random data it has generated in memory 23 and subsequently transfers this data to the complementary OTP apparatus 20. It will be appreciated that the random data could have been generated when the generator 24 was in communication with the apparatus 20 and then subsequently passed by the generator 24 to the device 10. It would also be possible for the generator 24 to only generate random data when in communication both the device 10 and apparatus 20 so that the random data is passed to both immediately, obviating the need for the memory 23. Conversely, the random data could be generated in advance of the trusted random data generator 24 being in communication with either of the device 10 and apparatus 20 in which case the random data is stored in memory 23 and subsequently passed to each of the device 10 and apparatus.

In the FIG. 2B form of the trusted random data generator 24, the random data is generated by the generator 24 acting alone FIG. 2C shows a different form of the trusted random data generator 24 in which a QKD arrangement is used to generate the OTP data—in the illustrated scenario, the trusted random data generator 24 includes a QKD transmitter 26 arranged to interact with a QKD receiver 25 in the apparatus 20 in order to generate secret random data. The QKD transmitter 26 and receiver 25 can, of course, be swapped around; furthermore, the OTP data could alternatively be generated by a QKD interaction between the trusted generator 24 and a QKD entity in the device 10. As with the FIG. 2B trusted random data generator 24, the generator 24 of FIG. 2C also includes a memory 23 for storing the generated random data prior to transfer to the device 10 (or to the apparatus 20 if the QKD interaction was with the device 10).

The trusted random data generator 24 can be totally independent of the OTP device 10 and OTP apparatus 20 or can be associated with one of these entities—for example, the trusted random data generator 24 can be run by a bank that also runs the OTP apparatus 20.

Returning now to a consideration of the provisioning block 14 of the device 10, rather than the secret random data being generated using a QKD subsystem or being received by the provisioning block 14 from an external source, the OTP provisioning block 14 can include a random data generator 17 for generating random data which is both used to provision the memory 13 with OTP data ,and passed via the data-transfer interface 12 directly or indirectly (including via a trusted data store) to other OTP apparatus with which the device 10 wishes to conduct OTP interactions. The random data generator is, for example, a quantum-based arrangement in which a half-silvered mirror is used to pass/deflect photons to detectors to correspondingly generate a “0”/“1” with a 50:50 chance; an alternative embodiment can be constructed based around overdriving a resistor or diode to take advantage of the electron noise to trigger a random event. Other techniques can be used for generating random data, particularly where a reduced level of security is acceptable—in such cases, some relaxation can be permitted on the randomness of the data allowing the use of pseudo random binary sequence generators which are well known in the art.

Where the secret random data is being received or being passed on via the classical data-transfer interface 12, it is highly desirable for the data to be encrypted (except possibly where a wired interface is being used to interface directly with OTP apparatus or a trusted data store). The encryption should not, of course, be based on the Vemam cipher using existing OTP data from the memory 13 since in this case as least as much OTP data would be consumed as newly provisioned; however the existing OTP data can be used to form a session key for the (relatively) secure transfer of the new secret random data.

It will be appreciated that the level of security that applies to the sharing of secret random data between the device 10 and other OTP apparatus sets the maximum level of security that can be achieved using a one-time pad formed from this data; accordingly, if the user of the device 10 wishes to use the OTP data held in the device 10 to achieve very high levels of security for data transfer from the device, then the initial sharing of the secret random data must involve corresponding levels of security; however, if the OTP data is only to be used for applications that do not warrant the highest levels of security, then the security surrounding secret random data sharing can be relaxed.

It will also be appreciated that the sharing of the secret random data used for the one-time pads is generally restricted to entities that know something about each other (such as their respective identities or some other attribute); accordingly, the sharing of the secret random data will normally be preceded by a verification or qualification process during which each entity satisfies itself that the other entity possesses appropriate attributes. This applies not only for the OTP device 10 and the complementary OTP apparatus 20, but also to the trusted data store 21 and the trusted random data generator 24 which should check the attributes of any entity purporting to entitled to receive OTP data before such data is passed on to that entity.

The provisioning block 14 can simply append newly-obtained secret random data to the existing OTP data in memory 13 or can combine the new secret random data with the existing OTP data using a merge function, the merged data then replacing the previous contents of the memory 13. Preferably, the merge function is such that an eavesdropper who has somehow managed to obtain knowledge of the new secret random data, cannot derive any part of the merged data without also having knowledge of the pre-existing OTP data in the memory 13. A wide range of possible merge functions exist including functions for encrypting the new secret random data using the existing OTP data for the encrypting key, and random permutation functions (it will be appreciated that whatever merge function is used, it must be possible for the complementary OTP apparatus to select and use the same function on its copy of the new secret random data and its existing OTP data). Merging of the new secret random data and existing OTP data otherwise than by aggregation, can only be done if the device 10 and the complementary OTP apparatus have the same existing OTP data which should therefore be confirmed between the device and apparatus before the new secret random data and existing OTP data are subject to merging. In this respect, it will be appreciated that the OTP device 10 and the complementary OTP apparatus may not have the same existing OTP data for a variety of reasons such as a failed communication between the device and apparatus resulting in one of them consuming OTP data but not the other. Of course, it will frequently be possible for the OTP device and the complementary OTP apparatus to cooperate such that if either of them still has OTP data already discarded by the other, then that entity also discards the same data (one method of doing this is described later). However, it will not always be possible for the device 10 and the complementary OTP apparatus to cooperate in this way, or even check whether they have the same existing OTP data, at the time that one or other of the device and apparatus is provided with new secret random data—for example, if the OTP device is being replenished with new secret random data by communication with a trusted random data generator, it may well be that the trusted random data generator is not concurrently in communication with the OTP apparatus, the new secret random data only being subsequently shared with the OTP apparatus. In this type of situation, the new secret random data must be appended to the existing OTP data rather than being merged with it.

OTP Consumption Block 15

The OTP consumption block 15 is arranged to carry out tasks (‘applications’) that require the use (‘consumption’) of OTP data from the memory 13; it is to be understood that, unless otherwise stated herein, whenever data is used from the OTP data held in memory 13, that data is discarded. As already indicated, the OTP consumption block 15 is preferably provided by arranging for the main processor of the device 10 to execute OTP application programs; however, the consumption block 15 can additionally/alternatively comprise specialized hardware processing elements particularly where the OTP application to be executed involves complex processing or calls for high throughput.

A typical OTP consumption application is the generation of a session key for the exchange of encrypted messages with the complementary OTP apparatus; in this case, the complementary OTP apparatus can generate the same session key itself. Of course, the device 10 can securely communicate with the complementary OTP apparatus by encrypting data to be sent using the Vemam cipher—however, this would require the use of as much OTP data as there was data to be exchanged and so give rise to rapid consumption of the OTP data from memory 13.

Another OTP consumption application is the evidencing that the device 10 (or its owner/user) possesses a particular attribute. As already noted, the distribution of the secret random data used for the one-time pads is generally restricted to entities that know something about each other, such as their respective identities or the possession of other particular attributes (in the present specification, reference to attributes possessed by an entity includes attributes of a user/owner of the entity). An example non-identity attribute is an access authorisation attribute obtained following a qualification process that may involve the making of a payment. The secret random data will only be shared after each entity (or a trusted intermediary) has carried out some verification/qualification process in respect of the identity or other attributes of the other entity concerned. This verification/qualification can simply be by context (a bank customer replenishing their device 10 from an OTP apparatus within a bank may be willing to accept that the secret random data being received is shared only with the bank); however, verification/qualification can involve checking of documentary evidence (for example, a paper passport), or an automatic process such as one based on public/private keys and a public key infrastructure. Whatever verification/qualification process is used to control the sharing of secret random data, once such sharing has taken place, OTP data based on the secret random data can be used to prove the identity or other attributes of the possessor of the OTP data. Thus, for example, if OTP apparatus knows that it shares OTP data with an OTP device 10 with identity “X”, then the device 10 can identify itself to the complementary OTP apparatus by sending it a data block from the top of its one-time pad; the apparatus then searches for this data block in the one or more OTP pads it possesses and if a match is found, it knows that it is communicating with entity “X”. To aid finding a match, the device 10 preferably sends the OTP apparatus an identifier of the one-time pad that the device is proposing to use.

As already noted, communication failures and other issues can result in different amounts of OTP data being held by the OTP device 10 and the complementary OTP apparatus; more particularly, the data at the top of the one-time pad held by device 10 can differ from the data at the top of the one-time pad held by the complementary OTP apparatus. This is referred to herein as “misalignment” of the one-time pads. It is therefore convenient for the OTP device and the complementary OTP apparatus to each obtain or maintain a measure indicating how far it has progressed through its OTP data; this measure can also be thought of as a pointer or index to the head of the OTP pad and is therefore referred to below as the “head index”. Preferably, the head index is taken as the remaining size of the OTP data; although other measurements can be used for the head index (such as how much OTP data has been used), measuring the remaining size of the OTP data can be done at any time and so does not require any on-going maintenance. Whatever actual numeric value of the measure used for the head index, in the present specification the convention is used, when discussing head index values, that the nearer the top of the one-time pad is to the bottom of the pad, the “lower” is the value of the head index.

The head index is used to correct for misalignment of the one time pads held by the device 10A and the complementary OTP apparatus as follows. At the start of any OTT interaction, the device 10 and complementary OTP apparatus exchange their head indexes and one of them then discards data from the top of its one-time pad until its head index matches that received from the other—that is, until the one-time pads are back in alignment at the lowest of the exchanged head index values. When OTP data is used by the device or apparatus in conducting the OTP transaction, the head index is sent along with the OTP interaction data (e.g. an OTP encrypted message) to enable the recipient to go directly to the correct OTP data in its one-time pad; this step can be omitted since although the one-time pads may have become misaligned by the time a message with OTP interaction data successfully passes in one direction or the other between the device and apparatus, this misalignment is likely to be small and a trial-and-error process can be used to find the correct OTP data at the receiving end.

The Complementary OTP Apparatus

With regard to the complementary OTP apparatus with which the OTP device 10 shares the same OTP data and can therefore conduct an OTP-based interaction, this can be constituted by apparatus in which all three functions of OTP storage, provisioning, and consumption are contained within the same item of equipment (as with the device 10); such OTP apparatus is referred to herein as “self-contained” OTP apparatus. However, it is also possible for the complementary OTP apparatus to be distributed in form with one of the OTP storage, provisioning, and consumption functions being in a separate item of equipment from the other two, or with all three functions in separate items of equipment to the OTP storage and provisioning functions; such OTP apparatus is referred to herein as “distributed” OTP apparatus. In distributed OTP apparatus it is, of course, necessary to ensure an adequate level of security for passing OTP data between its distributed functions.

It is conceivable that one or both of the provisioning and consumption functions are provided by equipment that is also used by another distributed OTP apparatus.

To illustrate the different roles that self-contained and distributed OTP apparatus can play, FIG. 3 shows the OTP device 10 conducting an OTP interaction with a distributed data processing system 27 such as a banking system. The distributed system 27 comprises a central computer facility 28 that communicates with a plurality of customer-interfacing units 29 by any suitable communications network. The device 10 can communicate with one or more of the units 29 using its classical data-transfer interface 12.

In one possible scenario, each of the units 29 is a self-contained OTP apparatus holding OTP data that is distinct from the OTP data held by any other unit 29; in this case, assuming that the device 10 only holds one pad of OTP data, it is restricted to interacting with the unit 29 that holds the same pad. Alternatively, the OTP device 10 can be arranged to hold multiple pads of OTP data each corresponding to a pad held by a respective one of the units 29, the device 10 then needing to use data from the correct pad for the unit 29 with which it wishes to conduct an OTP interaction.

In an alternative scenario, the central computer facility 28 is a self-contained OTP apparatus, the device 10 conducting the OTP interaction with the facility 28; in this case, each of the units 29 is simply a communications relay for passing on the OTP interaction messages.

In a further alternative scenario, the central computer facility 28 holds the OTP data shared with the device 10 but the units 29 are consumers of that data; in this case, the device 10 conducts the OTP interaction with one of the units, the unit obtaining the needed OTP data from the facility 28 over the internal network of the distributed system In this scenario, the distributed system 27 forms a distributed OTP apparatus.

It may be noted that in the last scenario, it is possible to arrange for each of the units 29 to be capable of taking part in an OTP provisioning operation with the device 10, either by passing on to the central computer facility 28 secret random data provided by the device 10, or by generating random data and passing it both to the device 10 and to the central facility 28; in this latter case, the units 29 independently generate their random data.

Whatever the form of the complementary OTP apparatus, it may have been designed to carry out OTP interactions with multiple different devices 10, each with its own OTP data. This requires that the complementary OTP apparatus hold multiple different pads of OTP data, one for each device 10 with which it is to conduct OTP interactions; it also requires that the OTP apparatus uses the correct OTP data when interacting with a particular OTP device 10. One way of enabling the OTP apparatus to determine quickly which is the correct pad of OTP data to use in respect of a particular device 10, is for each pad to have a unique identifier which the device sends to the apparatus when an OTP interaction is to be conducted. It is not necessary for this identifier to be sent securely by the device 10 (unless there are concerns about an eavesdropper tracking patterns of contact between particular devices and the apparatus).

Variable-n-Time Pad

In order to reduce the need to re-provision the device 10 with OTP data, it is possible to arrange for data from the one-time pad to be used more than once where the security requirements permit such a reduction in the level of security; such a pad is referred to as an “n-time pad” where ‘n’ is an integer indicating the maximum number of times that data from the pad can be used (for example, n=3). In the following, the abbreviation “NTP” is used for “n-time pad” in the role of a qualifier; thus, for example, data from the n-time pad is referred to as NTP data.

Typically where a pad held by the device 10 is used as an n-time pad, the pad is treated as divided into NTP data blocks and a usage count kept for each data block to track how many times it has been used by the consumption block 15. The consumption block 15 is no longer arranged to discard each data block after first use but is, instead, arranged to update the associated usage count of a data block after using it and only to discard the data block when this count reaches the predetermined fixed usage limit value n (in practice, the consumption block 15 would automatically discard a data block following use where that block had a count value of n−1 when taken from the n-time pad). Assuming that all consumption applications run by the consumption block 15 have a security level that makes it is acceptable to use an NTP block that has already been used (n−1) times, the consumption block 15 can simply use the top block from the one-time pad without being concerned whether it has been previously used (on the basis that the one-time pad will not contain data blocks that have been used more than n−1 times).

Embodiments of the invention will now be described which enable an n-time pad to be managed in such a way that the pad can be used for applications with any security level, that is, both for applications requiring one-time only use of pad data and applications with security levels that can tolerate multiple uses of the pad data. In other words, the value of n is variable over the pad with the value of n associated with pad data block(s) used by a particular application, being no greater than the security level of the application.

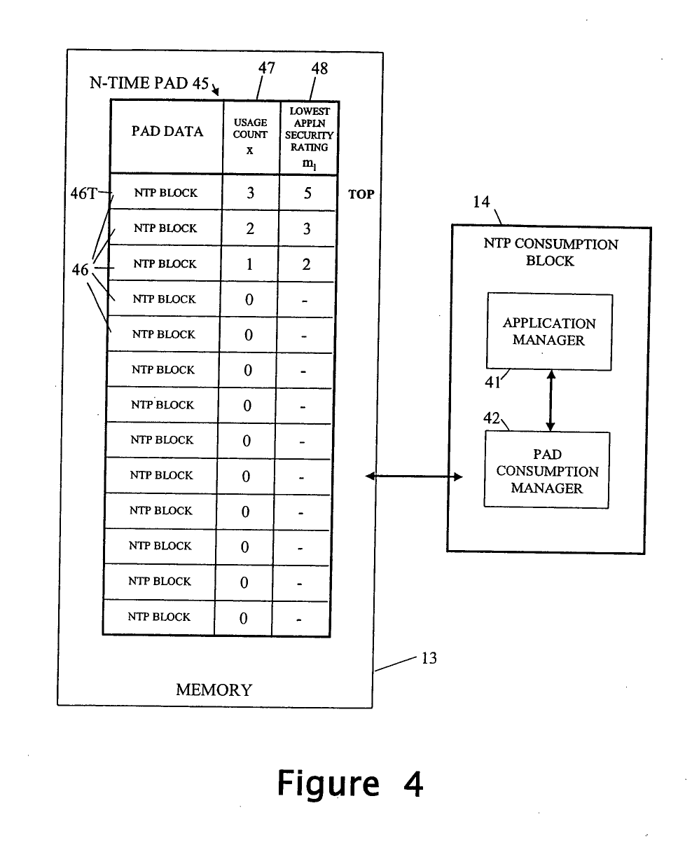

FIG. 4 depicts a n-time pad 45 held in the memory 13 of the device 10, the pad being divided into NTP data blocks 46 of which the block 46T constitutes the block at the top of the pad. The size of each NTP data block is, for example, that of the standard amount of data consumed by applications executed by the consumption block 15 (for example, 32 bits).

Each application (or task) that consumes data from the pad is given a security rating ‘m_{A}’ in terms of the maximum number of times the pad data used by the application can be used in total (by the same or different applications)—thus a value of ‘1’ for m_{A} corresponds to requiring the use of one-time pad data whereas a value of ‘3’ corresponds to requiring the use of pad data that, at most, has already been used twice.

For each NTP data block 46, the pad 45 stores two parameter values, namely a block usage count x (see column 47), and the value m_{L} of the lowest security rating of all the applications that have used that block (see column 48); for an unused block 46, x has a value of zero and m_{L} has a null value (effectively equivalent to an infinite value).

For use with the n-time pad 45, the form of the consumption block 15 shown in FIG. 1 is modified. In particular, in its embodiment shown in FIG. 4, the consumption block 15 comprises an application manager 41 arranged to execute a current NTP-data-consuming application, and a pad consumption manager 42 arranged to manage the n-time pad 45 and provide the application manager 41 with suitable NTP data for use by the current application.

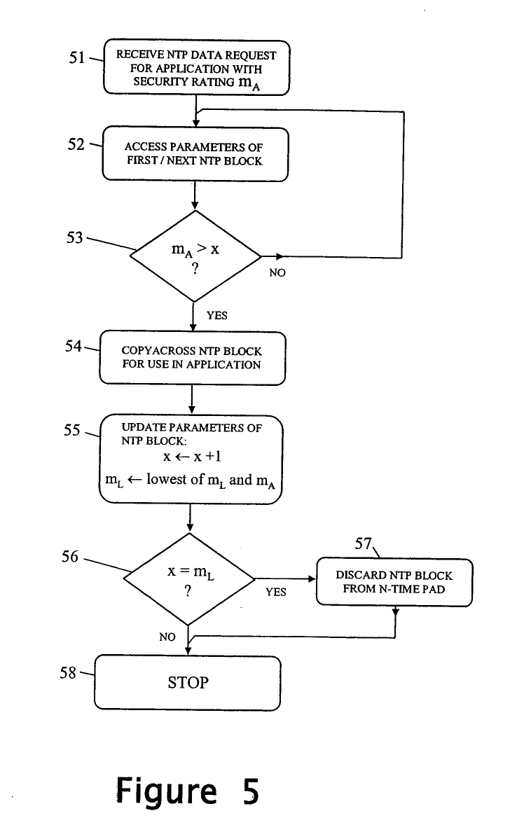

FIG. 5 is a flow chart showing the operation of the pad consumption manager 42. When the application manager 41 wishes to execute an application with a security rating of M_{A}, it makes a request to the pad consumption manager 42 for suitable pad data, this data including the application security rating m_{A}. In step 51 of the FIG. 5 flow chart, the pad consumption manager 42 receives the request from the application manager 41.

In step 52, the pad consumption manager 42 accesses the parameters of the first block (block 46T) of the n-time pad 45. In step 53 the pad consumption manager 42 checks whether the application security rating m_{A} is greater than the usage count x of the block being considered. If the value of m_{A} is greater than the usage count value x, then the block under consideration is suitable for use by the current application; in this case, the pad consumption manager 42 copies the block to the application manager 41 (step 54) for a single use by the current application. However, if the value of m_{A} is less than or equal to the usage count value x of the block under consideration, then the block is not suitable for use by the current application and the pad consumption manager 42 loops back to step 52 to access the parameters of the next NTP block 46 of the pad 45. Steps 52 and 53 are repeated until a suitable NTP block is found.

After step 54 has been carried out, the pad consumption manager 42 next proceeds to update the parameters of the NTP block that it copied to the application manager 41—see step 55. This updating involves incrementing the usage count value x and setting the lowest application security rating value m_{L} to the lowest of the previous value of m_{L} and the security rating m_{A} of the current application. Since the initial, default, value of M_{L} is effectively infinity, the first usage of the NTP block results in m_{L} being set to the value of m_{A} of the application concerned.

In step 56 the pad consumption manager 42 checks whether the updated usage count value x equals the updated lowest application security rating value m_{L}. If these two values are equal, the block concerned is discarded (step 57); otherwise the block is retained as not having reached its maximum number of usages. Thereafter, the pad consumption manager 42 terminates its processing (step 58).

In this manner, the number of times an NTP block is used is determined by the security rating of the highest-security application using the data (this application having the lowest valued security rating m_{A}). The NTP block can be used for applications of various different security ratings; to find a suitable NTP block for use with the higher-security applications, it will generally be necessary to pass over the blocks at the top of the NTP pad to find a less-used or unused NTP block.

It will be appreciated that the absolute maximum number of times any NTP data block can be used is set by the highest permitted value of the application security rating m_{A}; thus if the highest rating permitted is 5 (for applications requiring the least security) then at most an NTP data block will only be used 5 times and then only if every use is by an application with a value of m_{A} equal to 5.

It is, of course, possible to achieve the same purpose as the FIG. 5 process using differently-expressed parameters. For example, rather than storing for each NTP block the above-described ‘lowest application security rating’ parameter m_{L}, a related “usages-remaining” parameter ‘y’ can be kept for each block where y is given a value at each update (corresponding to step 55 of FIG. 5) which is the lesser of:

the previous value of y minus 1, and

the difference between the updated value of the usage count x and the security rating m_{A}

The initial, default, value of y is effectively infinity so that the first usage of the block concerned results in y being set to m_{A}. Upon the value of y becoming zero (as tested, for example, in a step corresponding to step 56 of FIG. 5), the block is discarded.

Another way of achieving a result similar to that achieved by the FIG. 5 process is to specify a fixed maximum usage-life value Z (for example, Z=5) and to express the security rating w of the applications as a weighted usage count. The highest security applications that require the pad data to be used only once are given a security rating value w equal to the value of Z whereas the lowest security applications are given a security rating value w of 1. For each data block an aggregated used-life count Σw is kept corresponding to the sum of the security ratings of all applications that have used the data. A pad data block is usable for a current application only if the sum of its aggregated used-life count value Σw and the security rating of the application is no greater than the value of Z. A pad data block is discarded once its aggregated used-life count Σw equals Z. It can be seen that a higher security application makes greater inroads into the remaining life of a pad data block it uses than does a lower security application; a highest security application consumes all the usage life of a data block in one go.

It will be appreciated that although the consumption block 15 of the device 10 of FIG. 1 has been adapted to provide the functionality necessary to manage, as a variable-n-time pad, data formerly used for a one-time pad, the other functional blocks of the FIG. 1 device can remain substantially unchanged. In particular, the provisioning block 14 does not need to be modified.

Many other variants are possible to the above described embodiments of the invention. For example, although in the foregoing, embodiments of the invention have been described in relation to an NTP device that incorporates, in a self-contained form, NTP storage, provisioning, and consumption, it is to be understood that the device could generally be replaced by a distributed arrangement of its functional blocks.

1. A method of managing an n-time pad from which data is used in security-related tasks, wherein in order to accommodate use of the pad with security-related tasks of different security ratings, the maximum number of times any particular data from the pad is used is determined by the security rating of the highest-security application using that data.

2. A method according to claim 1, wherein the security rating of a said task is expressed as the maximum number of times, m_{A}, data from the n-time pad that is used in the task can be used in total, the method comprising
maintaining usage-related values concerning usage of data from the n-time pad;
selecting data from the n-time pad for use in a current said task based on the security rating of the task and said usage-related values; and
discarding data from the n-time pad upon the usage-related values for that data indicating that the data has been used a number of times corresponding the lowest security rating of the tasks that have used that data.

3. A method according to claim 2, wherein the n-time pad is divided into data blocks, the usage-related values comprising for each data block:
a usage count x indicative of how many time the data block has been used;
a lowest-security-rating value m_{L} indicative of the lowest security rating m_{A} of all the tasks that have used the data block;
a said data block being selected for use in a current said task only if its associated usage count x is less than the security rating m_{A} of the task, and the usage-related values associated with a said data block being updated in respect of use of the data block for a current said task by:
incrementing the usage count x and
setting the lowest-security-rating value m_{L} to the lesser of its previous value, if any, and the security rating of the current task;
a said data block being discarded when its associated values of x and m_{L} are equal.

4. A method according to claim 2, wherein the n-time pad is divided into data blocks, the usage-related values comprising for each data block:
a usage count x indicative of how many time the data block has been used;
a usages-remaining value y indicative of the number of times remaining that the data block can be used having regard to the security ratings of the tasks that have already used the data;
a said data block being selected for use in a current said task only if its associated usage count x is less than the security rating m_{A} of the task, and the usage-related values associated with a said data block being updated in respect of use of the data block for a current said task by:
incrementing the usage count x, and
setting the usages-remaining value y to the lesser of:
its previous value minus one, where such previous value exists, and
the difference between the updated value of its usage count x and the security rating m_{A} of the current task;
a said data block being discarded when its associated values of x and m_{L} are equal.

5. A method according to claim 1, wherein the security rating of a said task is expressed as a weighted usage count w the value of which is greater for higher security tasks, the method comprising
maintaining for each data block used from the n-time pad, an aggregated used-life count Σw corresponding to the sum of the security ratings w of all tasks that have used the data block;
selecting for use in a current said task, an n-time pad data block for which the sum of the aggregated used-life count Σw of that data block and the security rating w of the task is no greater than a maximum-usage-life value Z;
discarding a data block from the n-time pad upon the aggregated used-life count Σw for the data block equaling said maximum-usage-life value Z.

6. A device comprising:
a memory for holding an n-time pad and usage-related values concerning usage of data from the n-time pad, and
a consumption arrangement for using data from the n-time pad in executing security-related tasks
wherein, in order to accommodate use of the pad with security-related tasks of different security ratings, the consumption arrangement is so arranged that the maximum number of times any particular data from the pad is used is determined by the security rating of the highest-security application using that data.

7. A device according to claim 6, wherein the security rating of a said task is expressed as the maximum number of times, m_{A}, data from the n-time pad that is used in the task can be used in total; the consumption arrangement being arranged to:
maintain said usage-related values,
select data from the n-time pad for use in a current said task based on the security rating of the task and said usage-related values, and
discard data from the n-time pad upon the usage-related values for that data indicating that the data has been used a number of times corresponding the lowest security rating of the tasks that have used that data.

8. A device according to claim 7, wherein the usage-related values comprise for each of multiple data blocks of the n-time pad:
a usage count x indicative of how many time the data block has been used;
a lowest-security-rating value m_{L} indicative of the lowest security rating m_{A} of all the tasks that have used the data block;
the consumption arrangement being arranged to:
select a said data block for use in a current said task only if its associated usage count x is less than the security rating m_{A} of the task;
maintain said usage-related values by updating the usage-related values associated with a said data block being used for a current said task by:
incrementing the usage count x and
setting the lowest-security-rating value m_{L} to the lesser of its previous value, if any, and the security rating of the current task;
discard a said data block when its associated values of x and m_{L} are equal.

9. A device according to claim 7, wherein the usage-related values comprise for each of multiple data blocks of the n-time pad:
a usage count x indicative of how many time the data block has been used;
a usages-remaining value y indicative of the number of times remaining that the data block can be used having regard to the security ratings of the tasks that have already used the data;
the consumption arrangement being arranged to:
select a said data block for use in a current said task only if its associated usage count x is less than the security rating m_{A} of the task;
maintain said usage-related values by updating the usage-related values associated with a said data block being used for a current said task by:
incrementing the usage count x, and
setting the usages-remaining value y to the lesser of:
its previous value minus one, where such previous value exists, and
the difference between the updated value of its usage count x and the security rating m_{A} of the current task;
discard a said data block when its associated values of x and m_{L} are equal.

10. A device according to claim 6, wherein the security rating of a said task is expressed as a weighted usage count w the value of which is greater for higher security tasks; the consumption arrangement being arranged to:
maintain for each data block used from the n-time pad, a said usage-related value in the form of an aggregated used-life count Σw corresponding to the sum of the security ratings w of all tasks that have used the data block;
select for use in a current said task, an n-time pad data block for which the sum of the aggregated used-life count Σw of that data block and the security rating w of the task is no greater than a maximum-usage-life value Z; and
discard a data block from the n-time pad upon the aggregated used-life count Σw for the data block equaling said maximum-usage-life value Z.
